(19) United States
(12) Patent Application Publication
(10) Pub. No.: US 2006/0166394 A1
(43) Pub. Date: Jul. 27, 2006

(54) Solar cell structure with solar cells having reverse-bias protection using an implanted current shunt

(76) Inventors: Jerry R. Kukulka, Santa Clarita, CA (US); David E. Joslin, Valley Village, CA (US)

Correspondence Address: Carmen Santa Maria;McNees Wallace & Nurick LLC, 100 Pine Street, P.O. Box 1166, Harrisburg, PA, 17108-1166, US

(21) Appl. No.: 10/614,310

(22) Filed: Jul. 7, 2003

(51) Int. Cl. H01L 21/00; H01L 27/14; H01L 31/00

(52) U.S. Cl. 438/57; 257/431

(57) ABSTRACT

A solar cell structure includes a solar cell of two or more semiconductor layers in facing contact with each other. The semiconductor layers constitute a semiconductor junction producing a voltage between the semiconductor layers when illuminated. A shunt formed of an altered material extends between and at least partially through the semiconductor layers. The shunt has an asymmetric current-voltage characteristic of passing a small current when voltage-biased in a forward direction and passing a large current when voltage-biased in a reverse direction.

This invention relates to a solar cell structure and, more particularly, to a solar cell structure with individual solar cells that each have protection against damage when reverse biased.

### BACKGROUND OF THE INVENTION

A solar cell is formed of two semiconductor layers in facing contact with each other at a semiconductor junction. When illuminated by the sun or otherwise, the solar cell produces a voltage between the semiconductor layers. Advanced solar cells may include more than two semiconductor layers and their respective pairwise semiconductor junctions. The various pairs of semiconductor layers of the advanced solar cells form subcells, with each subcell tuned to a specific spectral component of the sun to maximize the power output. The voltage and current output of the solar cell are limited by the materials of construction and the surface area of the solar cell. Most commonly, a number of subcells are electrically interconnected in series to form a solar cell structure that produces higher voltages than are possible with the single junction solar cell. Such multijunction solar cell structures with up to three subcells are now used in both space and terrestrial applications. These solar cell structures work well when all of the subcells absorb about the same photon flux.

When single-junction or multijunction solar cells form a circuit of serially connected devices, and one of the solar cells in the circuit is shaded while the others remain fully illuminated, the shaded solar cell is subjected to a reverse-bias condition by the continuing voltage and current output of the remaining unshaded solar cells. Fortunately, each solar cell may be protected against the potential damage arising during the reverse-bias condition by a parallel diode that does not pass current when the solar cell is not reverse biased, but passes the impressed current when the solar cell is reverse biased. The diode thus protects the individual cell against reverse-bias damage.

A number of diode configurations are in use and are operable, but each has its drawbacks. In one configuration, a discrete diode is bonded to the backside of the solar cell and interconnected to the semiconductor layers of the solar cell with leads. This approach requires the bonding of the interconnection taps and the leads, a time-consuming process when a large number of solar cells are present in the solar cell circuit. In another configuration, the diode is grown onto the front surface of the solar cell as part of the deposition process and then interconnected to the next solar cell in series. This approach is complex and causes assembly difficulties as well as reduced production yields and reduced solar cell efficiency. In yet another configuration, the diode is also grown into the front surface of the solar cell and interconnected with discrete or lithographic techniques. This approach is also complex, and has reduced production yields and reduced solar cell efficiency.

There is a need for an improved approach to the protection of solar cells against reverse-bias damage. The present invention fulfills this need, and further provides related advantages. SUMMARY OF THE INVENTION

The present invention provides a solar cell structure comprising a solar cell protected against reverse-bias damage. The protection is afforded by a shunt internal to the solar cell, so that no external interconnections are required for the reverse-bias protection. The reverse-bias protection is accomplished by a few additional process steps that are readily accomplished using manufacturing procedures known in other contexts.

In accordance with the invention, a solar cell structure comprises a solar cell having two semiconductor layers in facing contact with each other. The semiconductor layers form a semiconductor junction producing a voltage between the two semiconductor layers when illuminated. There is a shunt comprising a channel of an altered material extending between and at least partially through the two semiconductor layers. The shunt has an asymmetric current-voltage characteristic of passing a small current when voltage-biased in a forward direction parallel to the channel, and passing a large current when voltage-biased in a reverse direction parallel to the channel and opposite to the forward direction.

The altered material of the channel is produced by any operable approach. In a preferred approach, the altered material is a proton-implanted or ion-implanted altered material. In another approach, the altered material is a doped altered material.

Although the present shunt approach is operable with a two-layer solar cell, the solar cell may comprise more than two semiconductor layers. In that case, the shunt may extend between and at least partially through at least three of the semiconductor layers. Instead, the shunt may extend between and at least partially through only two of the semiconductor layers, or it may extend between and at least partially through all of the semiconductor layers.

The shunt may be a single channel of the altered material oriented perpendicular to a front-side surface of the solar cell. More typically, the shunt comprises a plurality of such channels spaced apart from each other over a front-side face of the solar cell.

The solar cell structure may include a single solar cell with the described shunt. More typically, the solar cell structure comprises a plurality of monolithically or otherwise electrically interconnected solar cells, with each solar cell or subcell having a shunt as described above. The reverse-bias condition usually arises in practice in such arrays of electrically interconnected solar cells, and the reverse-bias protection is most beneficially utilized in relation to such arrays.

The shunt of the present approach electrically functions in the manner of a diode to prevent current flow therethrough when the solar cell is forward biased. In that case, the current flows in the forward direction. When the solar cell is reverse biased so that, absent the shunt, there would be a damaging reverse current flow through the cell, the shunt passes the current through the shunt channel rather than through the remainder of the solar cell, thereby preventing reverse-bias damage to the remainder of the solar cell.

The shunt is preferably formed by proton implantation or ion implantation. In the former, a beam of energetic protons disrupts the structure of the semiconductor layers along the shunt channel. In the latter, a beam of energetic ions is implanted along the shunt channel to disrupt the structure of the semiconductor layers. The implanted channel is thereafter preferably annealed so that the implanted ions become an activated dopant species. The dopant channel may alternatively be formed by a surface-deposition and diffusion process.

The present approach thus provides reverse-bias protection for the solar cell without the formation of an external diode and without any diode electrical interconnections. Other features and advantages of the present invention will be apparent from the following more detailed description of the preferred embodiment, taken in conjunction with the accompanying drawings, which illustrate, by way of example, the principles of the invention. The scope of the invention is not, however, limited to this preferred embodiment.

### BRIEF DESCRIPTION OF THE DRAWINGS

FIG. 1 is a schematic plan view of a solar cell structure having an electrically interconnected array of solar cells;

FIG. 2 is a block diagram of a first method for practicing a first embodiment of the invention;

FIG. 3 is a block diagram of a second method for practicing a second embodiment of the invention;

FIG. 4 is a schematic sectional view through a portion of the solar cell structure of FIG. 1, taken on line 4-4; and

FIG. 5 is a schematic current-voltage graph for the solar cell output and for the shunt current flow.

### DETAILED DESCRIPTION OF THE INVENTION

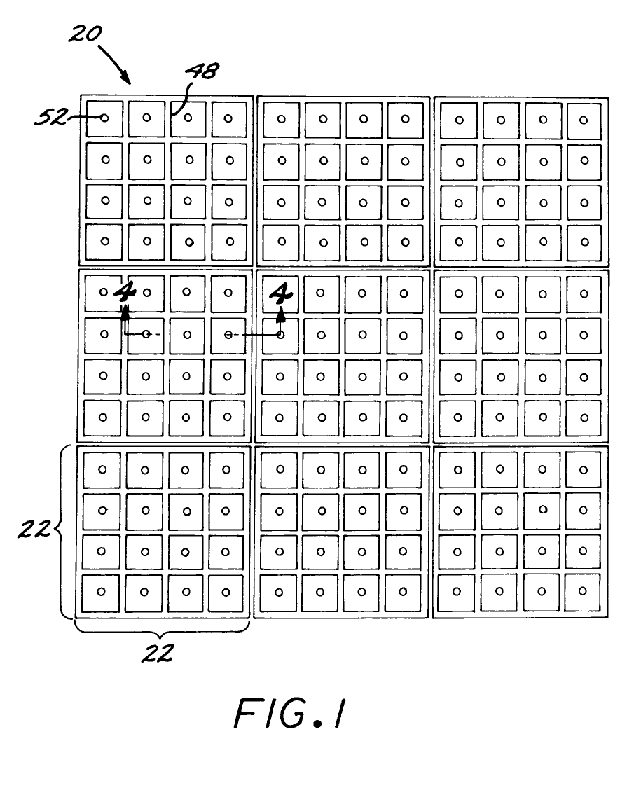

FIG. 1 depicts a solar cell structure 20 according to an embodiment of the invention, having an electrically interconnected array of individual solar cells 22. The electrical interconnections between the individual solar cells 22 are not visible in FIG. 1, but they may be electrical series and/or parallel interconnections.

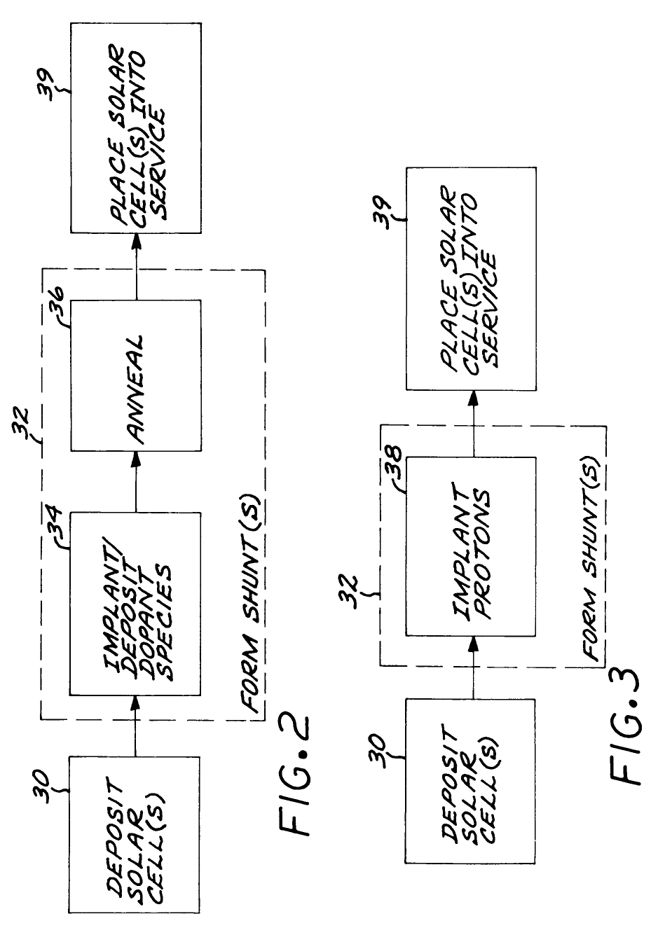

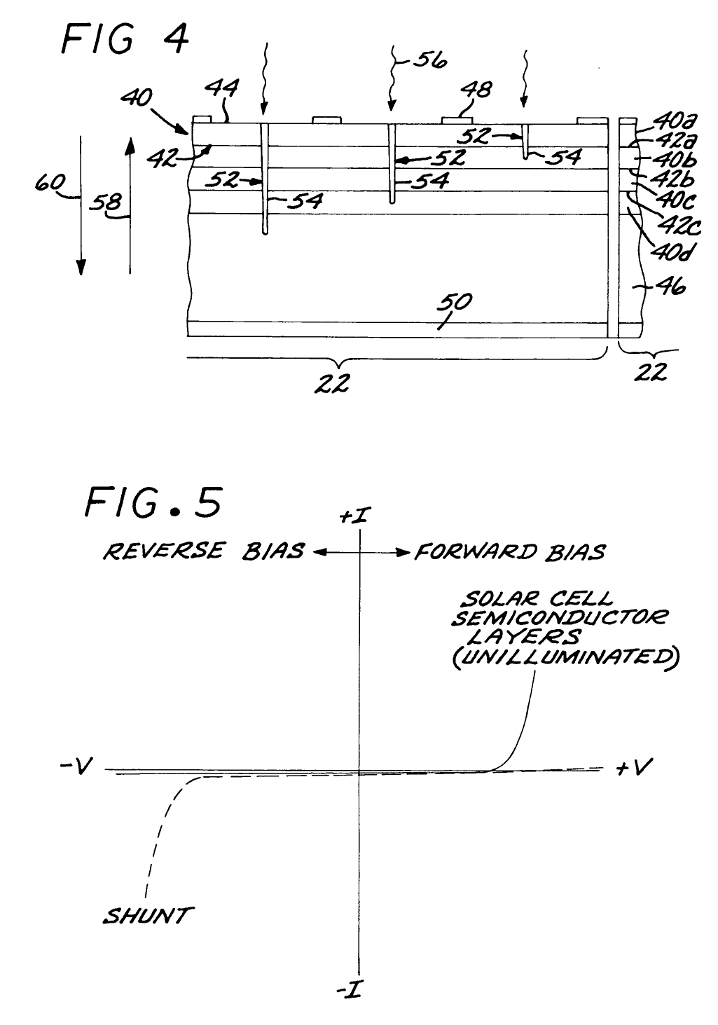

FIGS. 2-3 illustrate two approaches to fabricating the solar cell structure 20. FIG. 4 is a sectional view through a portion of the solar cell structure 20, made by either of the approaches of FIGS. 2-3. Common steps of the two approaches of FIGS. 2-3 are assigned the same reference numerals, and the discussion of those steps is applicable to both approaches. The description is applicable to the fabrication of one solar cell 22 or an array of solar cells 22 that constitute the solar cell structure 20, but it will be discussed for the array of solar cells 22 produced simultaneously because that is the usual and preferred practice.

The solar cells 22 are deposited, step 30. Each solar cell 22 comprises at least two, and typically more than two for advanced solar cells, active semiconductor layers 40 in facing contact with each other. The semiconductor layers 40 comprise at least one, and typically more than one for advanced solar cells, semiconductor junctions 42 producing a voltage between two facing and contacting semiconductor layers 40 when illuminated from a front-side surface 44. The semiconductor layers 40 are deposited upon a substrate 46. In an example illustrated in FIG. 4, there are three solar subcells formed from six adjacent and contacting semiconductor layers 40, and an associated three semiconductor junction 42: semiconductor layers 40a and 40b form semiconductor junction 42a; semiconductor layers 40c and 40d form semiconductor junction 42b; and semiconductor layers 40e and 40f form semiconductor junction 42c. There are two tunnel junctions 41a and 41b. Each tunnel junction 41 permits the continuous flow of current from one semiconductor junction 42 to another. A front side metal grid 48 and a back side metallization 50 are deposited to collect the current produced by the semiconductor junctions 42 when they are illuminated. This description of the deposition of the solar cells 22 is made to identify the major elements pertinent to the present discussion, and in actual practice the structures may be more complex, with additional layers and features such as tunnel junctions. Solar cell fabrication techniques, except for the modifications discussed herein, are known in the art, see for example U.S. Pat. No. 5,330,585, whose disclosure is incorporated by reference.

Shunts 52, each comprising a channel 54 of an altered material, are formed in the as-deposited solar cells 22, step 32. The shunts 52 extend between and at least partially through two semiconductor layers 40. There may be a single shunt 52, but more preferably and as illustrated, a plurality of shunts 52, spaced apart over the face of the solar cell 22, are formed. Each channel 54 may shunt only one of the subcells (i.e., extend through only one of the junctions 42), or they may shunt multiple ones of the subcells (i.e., extend through more than one of the junctions 42), as shown in FIG. 4. In any particular solar cell 22, all of the channels 54 may shunt the same subcells (i.e., pairs of layers 40) or, as illustrated, various of the channels 54 may shunt different ones or combinations of the subcells.

Each shunt 52 is a channel 54 of altered material extending from the front-side surface 44 of the solar cell 22 through at least two of the semiconductor layers 40 and toward, but typically not through, the substrate 46. The channels 54 are generally rod-shaped, but may be tapered somewhat from a larger transverse size at the front-side surface 44 (the usual case for a tapered channel 54) or from a smaller transverse size at the front-side surface 44.

FIGS. 2-3 illustrate two preferred approaches for forming the shunts 52 and the channels 54, step 32. In the approach of FIG. 2, a dopant species is implanted by ion implantation from the front-side surface 44 of the solar cell, or deposited upon the front-side surface 44 of the solar cell, step 34, as indicated schematically by arrows 56 in FIG. 4. The channels 54 are formed of a doped altered material in each case, whose type will depend upon the specific layer compositions. The transverse extent of the implantation or deposition, and thence the transverse area of the channels 54 at the front-side surface 44, is determined by a mask or pattern overlying the front-side surface 44. The technique of ion implantation is known and is described, for example, in U.S. Pat. No. 4,473,836. The technique of vapor deposition is known and is described, for example, in U.S. Pat. No. 4,321,099. After the ion implantation or species deposition, step 34, the solar cell 22 may be annealed, step 36, to activate the implanted ions or to diffuse the deposited species. (For the present purposes, the deposition of the dopant on the front-side surface 44 and its subsequent diffusion is within the scope of “implantation”.) The ion implantation approach produces the channels 54 directly to the depth determined by the energy of the ion implantation, and the deposition approach produces the channels 54 as a result of the diffusion of the surface-deposited species into the semiconductor layers 40. The energy of deposition in the case of ion implantation or the extent of diffusion in the case of surface deposition determines the depth (i.e., the furthest extent of the individual channel 54 from the front-side surface 44) of the channels 54 as illustrated in FIG. 4. As illustrated, the channels 54 may extend between and through all of the semiconductor layers 40, or only some of the semiconductor layers 40.

In the other preferred approach illustrated in FIG. 3, protons are implanted, step 38, using a proton beam from the front-side surface 44 through a mask or pattern in a manner comparable with the ion implantation discussed in relation to FIG. 2. The channels 54 are a proton-irradiated altered material in each case. Proton implantation differs from ion implantation in that proton implantation does not deposit a foreign dopant species into the semiconductor layers 40. The proton implantation instead creates damage tracks that define the channels 54. The technique of proton implantation is known and is described, for example, in U.S. Pat. No. 5,048,038.

The shunts 52 have an asymmetric current-voltage characteristic as illustrated in FIG. 5. FIG. 5 illustrates the current (I)-voltage (V) curves for both the solar cell semiconductor layers 40 and the individual shunts 52. (A forward direction 58 is parallel to the channels 54 and typically perpendicular to the front-side surface 44, extending from the interior of the solar cell toward the front-side surface 44; a reverse direction 60 is parallel to and opposite to the forward direction 58, see FIG. 4.) The semiconductor layers 40 produce little current when reverse voltage biased in the reverse direction 60 but an increasing current when forward voltage biased in the forward direction 58. The shunts 52 pass a small current when forward voltage biased in the forward direction 58, and pass a large current when reverse voltage biased in the reverse direction 60.

The result is that, when the solar cell 22 is operating in its normal illuminated mode and is forward biased, it produces a relatively large current. A very small portion of that produced current is leaked in the reverse direction by the shunt 52, so that the efficiency of the solar cell 22 is slightly reduced. However, if the individual solar cell 22 is reverse biased, as for example when it is shaded and the remainder of the solar cells 22 in the solar cell structure 20 are operating in the forward biased mode so that they create current, the shunt 52 has a sufficiently high current leakage rate that the impressed current does not damage the reverse-biased (shaded) solar cell 22. The reverse-biased solar cell 22 is thereby protected in the manner of a diode, but without the external connections required for a conventional diode.

The implantation of protons or dopant species allows the subcells to be manipulated independently of each other. That is, base and emitter regions of the subcells may be intentionally damaged or compensated separately by selecting the implant species and energy. The damage and concentration of the implanted element at the end of its range increases markedly, and the characteristics are calculated using the known approach based upon proton radiation damage studies as a function of implantation depth. Not all cell elements need to be modified, but the nonlinear behavior of the cells may be optimized using this approach.

This shunting effect is not achieved during normal operations of conventional solar cells, because naturally occurring radiation is not mono-energetic, as is the case for the preferred ion implantation and proton implantation approaches, and the coverglass on space solar cells reduces, to an acceptable level, the intense damage associated with space protons and helium nuclei at the ends of their ranges as they penetrate the semiconductor layers in the device.

After the step 32 of forming the shunts 52 is complete, the solar cell structure 20 is placed into service, step 39. Step 39 may not be performed prior to the completion of the forming step 32, or the protection of the shunts will not be realized.

Although a particular embodiment of the invention has been described in detail for purposes of illustration, various modifications and enhancements may be made without departing from the spirit and scope of the invention. Accordingly, the invention is not to be limited except as by the appended claims.

What is claimed is:

1. A solar cell structure comprising:
a solar cell comprising two semiconductor layers in facing contact with each other, wherein the semiconductor layers comprise a semiconductor junction producing a voltage between the two semiconductor layers when illuminated; and
a shunt comprising a channel of an altered material
extending between and at least partially through the two semiconductor layers, and
having an asymmetric current-voltage characteristic of passing a small current when voltage-biased in a forward direction parallel to the channel, and passing a large current when voltage-biased in a reverse direction parallel to the channel and opposite to the forward direction.

2. The solar cell structure of claim 1, wherein the altered material is a proton-irradiated altered material.

3. The solar cell structure of claim 1, wherein the altered material is a doped altered material.

4. The solar cell structure of claim 1, wherein the solar cell comprises more than two semiconductor layers, and wherein the shunt extends between and at least partially through at least two of the semiconductor layers.

5. The solar cell structure of claim 1, wherein the solar cell comprises more than two semiconductor layers, and wherein the shunt extends between and at least partially through at least three of the semiconductor layers.

6. The solar cell structure of claim 1, wherein the shunt comprises a plurality of channels spaced apart from each other over a front-side surface of the solar cell.

7. The solar cell structure of claim 1, wherein the solar cell structure comprises a plurality of electrically interconnected solar cells as recited in claim 1, with each solar cell having a shunt as recited in claim 1.

8. A method for fabricating a solar cell structure, comprising the steps of
depositing a solar cell comprising two semiconductor layers in facing contact with each other, wherein the semiconductor layers comprise a semiconductor junction producing a voltage between the two semiconductor layers when illuminated;
forming a shunt comprising a channel of an altered material
extending between and at least partially through the two semiconductor layers, and
having an asymmetric current-voltage characteristic of passing a small current when voltage-biased in a forward direction parallel to the channel, and passing a large current when voltage-biased in a reverse direction parallel to the channel and opposite to the forward direction.

9. The method of claim 8, wherein the step of depositing includes the step of
depositing more than two semiconductor layers, and the step of forming includes the step of
forming the shunt to extend between and at least partially through at least two of the semiconductor layers.

10. The method of claim 8, wherein the step of depositing includes the step of
depositing more than two semiconductor layers, and the step of forming includes the step of
forming the shunt to extend between and at least partially through at least three of the semiconductor layers.

11. The method of claim 8, wherein the step of forming a shunt includes a step of
directing a proton beam into the semiconductor layers.

12. The method of claim 8, wherein the step of forming a shunt includes a step of
doping the channel.

13. The method of claim 8, wherein the step of forming a shunt includes steps of
doping the channel by ion implantation, and
annealing the channel.

14. The method of claim 8, wherein the step of forming includes a step of
forming a plurality of channels spaced apart from each other over a front-side surface of the solar cell.

15. The method of claim 8, including an additional step, to occur after the step of forming the shunt is complete, of
placing the solar cell structure into service.
